(19) United States
(12) Patent Application Publication
(10) Pub. No.: US 2015/0372068 A1
(43) Pub. Date: Dec. 24, 2015

(54) DISPLAY DEVICE

(71) Applicant: InnoLux Corporation, Miao-Li County (TW)

(72) Inventors: Cheng-Hsu CHOU, Miao-Li County (TW); I-Ho SHEN, Miao-Li County (TW); Chih-Hsiung CHANG, Miao-Li County (TW)

(21) Appl. No.: 14/739,219

(22) Filed: Jun. 15, 2015

(30) Foreign Application Priority Data
Jun. 23, 2014 (TW) 103121524

(51) Int. Cl. H01L 27/32; G02F 1/1362; H01L 51/05; G02F 1/1368; H01L 29/786; H01L 29/24

(52) U.S. Cl. CPC H01L 27/3272; H01L 29/7869; H01L 29/24; H01L 29/78654; H01L 29/78663; H01L 29/78672; H01L 51/0558; H01L 27/3274; H01L 29/78633; G02F 1/1368; G02F 1/136277; H01L 2251/558

(57) ABSTRACT

A display device includes a substrate, a thin film transistor unit disposed on the substrate, and a shielding unit disposed between the substrate and the thin film transistor unit. The thin film transistor unit includes a gate, an insulating layer, a semiconductor layer, a source, and a drain. The shielding unit includes a shielding layer and a first buffer layer. The first buffer layer is disposed between the shielding layer and the thin film transistor. Light with a wavelength of 200 nm to 510 nm has a transmittance between 0 to 15% when passing through the shielding layer.

### CROSS REFERENCE TO RELATED APPLICATION

This application claims the benefits of the Taiwan Patent Application Serial Number 103121524, filed on Jun. 23, 2014, the subject matter of which is incorporated herein by reference.

### BACKGROUND OF THE INVENTION

1. Field of the Invention

The present invention relates to a display device and, more particularly, to a display device capable of improving thin film transistor unit stability.

2. Description of Related Art

With advances in display technology, demands for the electronic devices from users are increasing, and all those devices are developed toward the trends of small size, slight thickness, light weight and the likes. Therefore, the major display devices in the market have been developed into liquid crystal display devices (LCD) or organic light emitting diode devices (OLED).

Generally, in LCD or OLED, the energy gap of the thin film transistor (TFT) unit of the active layer thereof is close to the ultraviolet (UV) light band or the blue light band; therefore, TFT behavior is sensitive to the UV light, the purple light, and the blue light. Extra electron holes may be induced in TFT while the active layer being irradiated by the UV light, the purple light, or the blue light (for example, irradiation of the UV light, the purple light, or the blue light during the manufacturing process, or irradiation of the UV light, the purple light, or the blue light from the external environment), resulting in that a carrier channel of the TFT contains extra electron holes, which affects TFT electrical shift, such as a negative shift of threshold voltage (Vth) and an increasing leakage current. Furthermore, there is a light leakage phenomenon occurred in an OLED under dark operation, or the shift register (S/R), data multiplexer, and other driving circuits may not work properly.

Therefore, it is desirable to provide a display device with improved display quality and service life, thereby providing a stable and high-quality display to consumers.

### SUMMARY OF THE INVENTION

The object of the present invention is to provide a display device, in which the TFT in the display device is less affected by UV light, purple light, and blue light, thereby improving stability and display quality of the display device.

To achieve the object, the display device of the present invention comprises a substrate; a thin film transistor unit disposed on the substrate, the thin film transistor unit including a gate electrode, an insulating layer, a semiconductor layer, a source electrode, and a drain electrode; and a shielding unit disposed between the substrate and the thin film transistor unit, the shielding unit including a shielding layer and a first buffer layer, wherein the first buffer layer is disposed between the shielding layer and the thin film transistor, in which light with a wavelength of 200 nm to 510 nm has a transmittance between 0 to 15% when passing through the shielding layer.

Accordingly, the present invention utilizes the shielding unit to absorb short-wavelength lights (such as the UV light, the purple light, or the blue light irradiated during the manufacturing process, or the UV light, the purple light, or the blue light from the external environment), and decrease the strength of those short-wavelength lights passing through the shielding unit. As a result, it is able to effectively reduce cases where those short-wavelength lights contact the active layer channel of the TFT, thereby reducing the electrical shift of TFT and alleviating the light leakage phenomenon of a display device under dark operation, or avoiding problems that the shift register (S/R), data multiplexer, and other driving circuits may not work properly. Therefore, the display device of the present invention exhibits a stable and high-quality display effect.

### BRIEF DESCRIPTION OF THE DRAWINGS

FIG. 1 illustrates a preferred embodiment of the thin film transistor unit in accordance with the present invention;

FIG. 2 illustrates another preferred embodiment of the thin film transistor unit in accordance with the present invention;

FIG. 3 illustrates a further preferred embodiment of the thin film transistor unit in accordance with the present invention;

FIG. 4 illustrates a preferred embodiment of the display device of the present invention;

FIG. 5 illustrates another preferred embodiment of the display device in accordance with the present invention;

FIG. 6 illustrates a further preferred embodiment of the display device in accordance with the present invention;

FIG. 7 illustrates the reflective index and the transmittance corresponding to different wavelengths based on the configuration of FIG. 1;

FIG. 8 is a comparison result showing the light intensity corresponding to different wavelengths between a case where LED backlight of an LCD passes through the shielding unit and a case where

LED backlight of an LCD does not pass through the shielding unit based on the configuration of FIG. 1; and

FIG. 9 is a result showing the examination of negative bias illumination stress (NBIS) based on the configuration of FIG. 1.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. Other various aspects also may be practiced or applied in the invention, and various modifications and variations can be made without departing from the spirit of the invention based on various concepts and applications.

### Embodiment 1

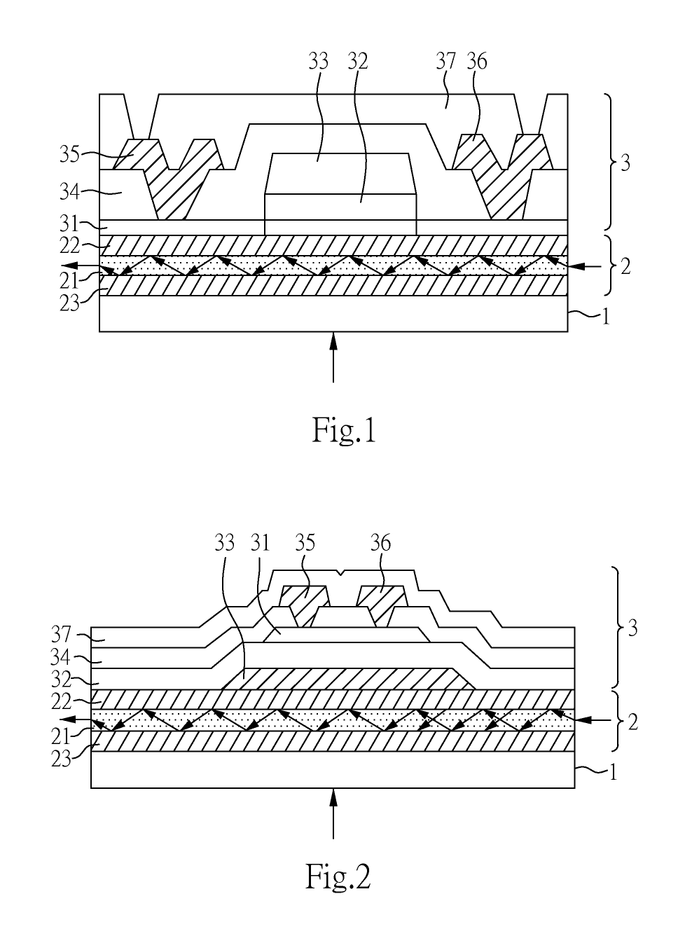

As shown in FIG. 1, the display device of the present invention comprises: a substrate 1; a thin film transistor unit 3 disposed on the substrate 1, wherein the thin film transistor unit 3 includes a semiconductor layer 31, an insulating layer 32, a gate 33, a first passivation layer 34, a source 35, a drain 36, and a second passivation layer 37; and a shielding unit 2 disposed between the substrate 1 and the thin film transistor unit 3, wherein the shielding unit 2 includes a shielding layer 21 and a first buffer layer 22 disposed between the shielding layer 21 and the thin film transistor 3, and the shielding unit 2 may further include a second buffer layer 23 disposed between the shielding layer 21 and the substrate 1.

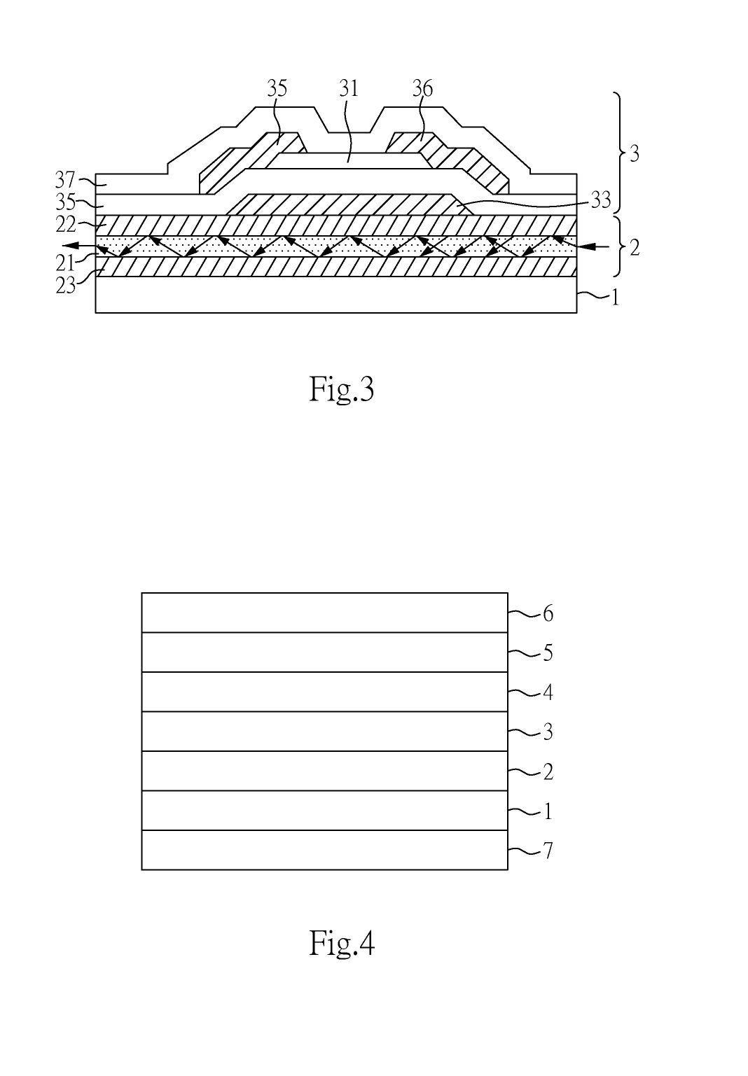

In this embodiment, the thin film transistor 3 may be manufactured by a known thin film transistor manufacturing process, and thus a detailed description therefor s deemed unnecessary. FIG. 1 illustrates a top gate thin film transistor. Alternatively, a bottom gate thin film transistor may also be used in the present invention. The configuration of the thin film transistor 3 may be adjusted by those skilled in the art. For example, the etching stop layer structure (ESL) shown in FIG. 2 or the back channel etching structure (BCE) shown in FIG. 3 may be used in the present invention.

Besides, a substrate widely used in the related fields, such as a glass substrate, a plastic substrate, a silicon substrate, and a ceramic substrate, may be used as the substrate 1 of the present invention. Furthermore, materials for the gate 33, the source 35, and the drain 36 may be conductive materials commonly used in the related fields. The conductive materials may be, for example, metals, alloys, metal oxides, metal oxynitrides, and the likes, or common electrode materials used in the field, in which the metals are preferred, but the present invention is not limited thereto. As for the material of the insulating layer 32, the gate insulating materials commonly used in the field, for example, silicon nitride (SiNx), silicon oxide (SiOx), or a combination thereof, may be used. Semiconductor materials that are commonly used in the field may be used for the semiconductor layer 31. The semiconductor materials may be, for example, indium gallium zinc oxide (IGZO), indium tin zinc oxide (ITZO), other metal oxide semiconductor, amorphous Si, polysilicon, crystalline Si, and other organic semiconductors such as P13, DH4T, pentacene, and the likes. In addition, materials for the first passivation layer 34 and the second passivation layer 37 may be passivation materials known in the related fields, such as silicon nitride (SiNx), silicon oxide (SiOx), or a combination thereof; however, the present invention is not limited thereto.

In this embodiment, when passing through the shielding layer 21, the light with a wavelength of 510 nm or less (especially the UV light, the purple light, or the blue light that has a wavelength of 200 nm to 510 nm) has a transmittance of 15% or less. Therefore, among those lights from the external environment, most of the lights with a wavelength ranged from 200 nm to 510 nm (e.g. the UV light, the purple light, or the blue light irradiated during the manufacturing process, or the UV light, the purple light, or blue light from the external environment) will be blocked by the shielding layer 21, thereby preventing those lights from negatively effecting the thin film transistor 3.

As for the shielding unit 2, the property of the shielding layer 21 is not particularly limited. A refractive index (n) of the shielding layer 21 is preferably in the range from 4.5 to 6 for the light with a wavelength of 365 nm to 510 nm; an extinction coefficient (k) of the shielding layer 21 is preferably in the range from 0.5 to 6 for the light with a wavelength of 200 nm to 510 nm; and a thickness of the shielding layer 21 is preferably in the range from 120 nm to 400 nm. In the case where the aforementioned preferable ranges are satisfied, the material of the shielding layer 21 may be amorphous Si, polysilicon, crystalline Si, or a combination thereof, but is not limited thereto.

In the shielding unit 2, there is no specific limitation on the first buffer layer 22 and the second buffer layer 23. Refractive index (n) of each of the first buffer layer 22 and the second buffer layer is preferably in the range from 1 to 2.3 for the light with a wavelength of 200 nm to 510 nm; and extinction coefficient (k) of each of the first buffer layer 22 and the second buffer layer 23 is preferably in the range from 0 to 2.7 for the light with a wavelength of 200 nm to 510 nm. In the case where the aforementioned preferable ranges be satisfied, the first buffer layer 22 and the second buffer layer 23 may be made from silicon oxide (SiOx), silicon nitride (SiNx), titanium nitride (TiOx), titanium silicide, aluminum oxide, nickel silicide, or a combination thereof.

Consequently, the refractive index (n) of the shielding layer 21 is preferably larger than the refractive index (n) of the buffer layers (the first buffer layer 22 and the second buffer layer 23). By utilizing the differences of the refractive index (n) between the shielding layer 21 and the buffer layers (the first buffer layer 22 and the second buffer layer 23), lateral lights (the UV light, the purple light, or the blue light irradiated during the manufacturing process, or the UV light, the purple light, or blue light from the external environment) with wavelengths satisfying the aforementioned limitations will be restricted in the shielding layer 21 by a guiding mode.

In addition, in the case when the thin film transistor 3 is a bottom gate thin film transistor, the metal layer of the gate electrode 33 may block the forward light incident from the lower substrate 1; however, due to the metal layer of the gate electrode 33 usually being patterned and the high reflectivity of metal, the lateral incident light may irradiate the thin film transistor 3 in a reflection or scattering manner, thereby negatively affecting the performance of the display device. Therefore, with the shielding unit 2 disposed between the substrate 1 and the thin film transistor 3, the lateral incident light can be blocked efficiently.

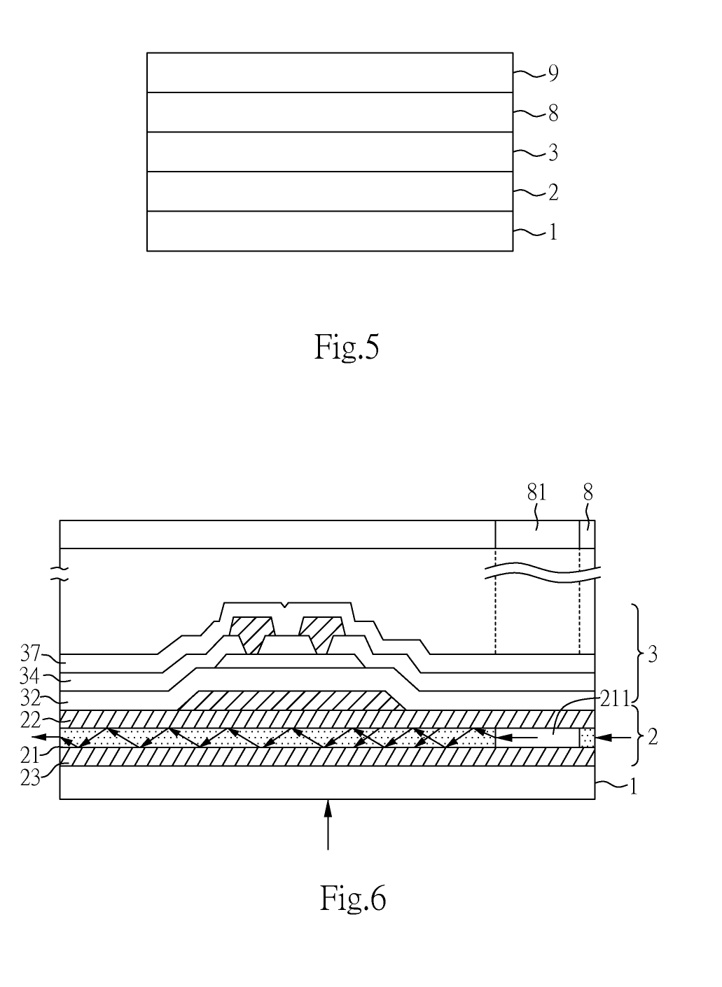

For illustrative purpose, FIG. 1 omits other components of the display device, which is, for example, an organic light emitting diode (OLED) display device or a liquid crystal display (LCD) device. With reference to FIG. 4 illustrating an LCD device, in addition to the substrate 1, the shielding unit 2, and the thin film transistor unit 3 as mentioned above, the LCD device further includes a liquid crystal unit 4, a color filter unit 5, a second substrate 6, and a back light module 7. Furthermore, with reference to FIG. 5 illustrating an OLED display device, in addition to the substrate 1, the shielding unit 2, and the thin film transistor unit 3 as mentioned above, the OLED display device further includes an organic light-emitting diode 8 and a packaging unit 9. Besides, other omitted components may be understood by those skilled in the art, and the components commonly used in the related fields may also be used in the present invention.

### Embodiment 2

With reference to the display device of FIG. 6, the components are identical to FIG. 2 except the shielding layer 21, and thus, the same parts will not be repeatedly described, and the descriptions of the embodiment 1 can be applied in the embodiment 2. In this embodiment, the provided display device is a bottom emitting OLED display device, and the organic light emitting diode 8 disposed on the thin film transistor unit 3 includes a light emitting area 81. A pattering process is performed on the shielding layer 21 to form an opening 211, which corresponds to the light-emitting area 81, wherein the size or the shape of the opening 211 is not limited and may be adjusted by those skilled in the art based on the actual conditions or requirements. As a result, because the portion corresponding to the light-emitting area 81 does not have the shielding layer 21, the light will not be blocked by the shielding layer 21 when the display device emits light downward, and thus the performance of external light emitting efficiency is not influenced.

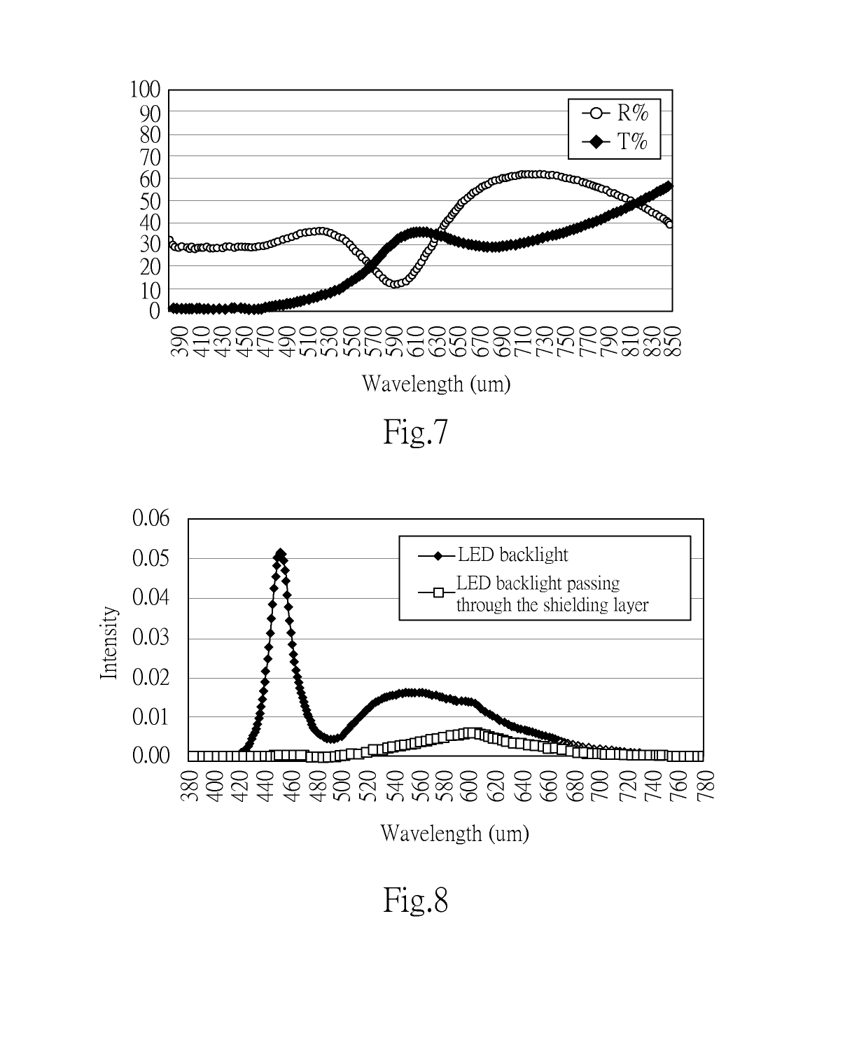

A measurement is performed to the reflective index and the transmittance of the shielding unit of FIG. 1, in which the substrate 1 is a glass substrate 1, each of the first buffer layer 22 and the second buffer layer 23 is SiOx with a thickness of 200 Å, and the shielding layer 21 is an amorphous Si with a thickness of 1200 Å. Under the irradiation of lights with different wavelengths, FIG. 7 shows the reflective index (R %) and the transmittance (T %) of lights. With reference to FIG. 7, it is obvious that the transmittance of the light with a wavelength of 510 nm or less is about 10% or less due to the block of the shielding layer, which confirms that the display device of the present invention can effectively block the short-wavelength light.

Furthermore, when the LED backlight is used for irradiation, the illumination of the LED backlight is 973 nits, and the illumination becomes 234 nits once after the irradiated light passes through the shielding unit of FIG. 1. FIG. 8 is a measurement result showing the light intensities under different wavelengths, which clearly indicates that the light with a wavelength of 510 nm or less is effectively blocked by the shielding layer.

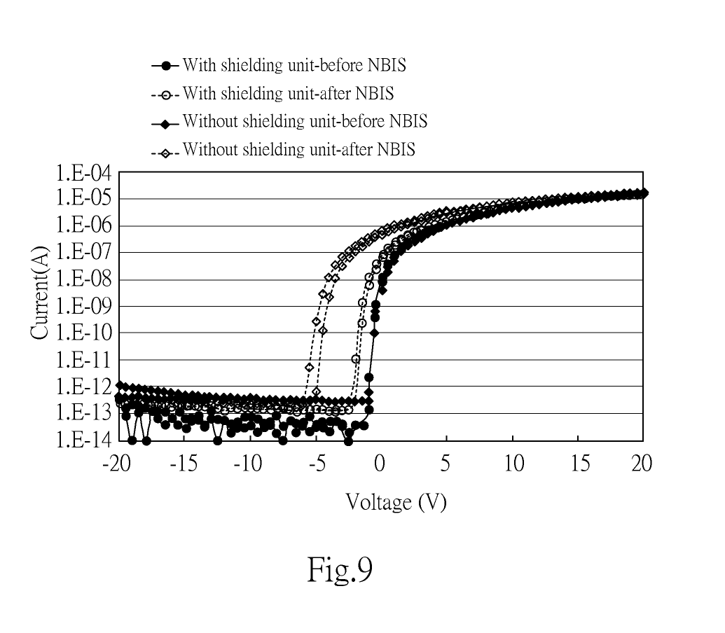

Next, a negative bias illumination stress (NBIS) examination is performed, and the result is shown in FIG. 9. At an illumination of 5160 nits, the group without the shielding unit exhibits a severe negative shift on threshold voltage (Vth) when applying a bias voltage of −30V to the gate. In comparison, the display device of the present invention exhibits insignificant negative shift on threshold voltage (Vth), thereby effectively eliminating the problems of the prior display device.

Although the present invention has been explained in relation to its preferred embodiment, it is to be understood that many other possible modifications and variations can be made without departing from the spirit and scope of the invention as hereinafter claimed.

What is claimed is:

1. A display device, comprising:
a substrate;
a thin film transistor unit disposed on the substrate, the thin film transistor unit including a gate, an insulating layer, a semiconductor layer, a source, and a drain; and
a shielding unit disposed between the substrate and the thin film transistor unit, the shielding unit including a shielding layer and a first buffer layer,
wherein the first buffer layer is disposed between the shielding layer and the thin film transistor,
wherein light with a wavelength of 200 nm to 510 nm has a transmittance between 0 to 15% when passing through the shielding layer.

2. The display device as claimed in claim 1, wherein a refractive index (n) of the shielding unit is in a range from 4.5 to 6 for light with a wavelength of 365 nm to 510 nm.

3. The display device as claimed in claim 1, wherein an extinction coefficient (k) of the shielding unit is in a range from 0.5 to 6 for light with a wavelength of 200 nm to 510 nm.

4. The display device as claimed in claim 1, wherein a thickness of the shielding unit is in a range from 120 nm to 400 nm.

5. The display device as claimed in claim 1, further comprising an organic light emitting diode (OLED) disposed on the thin film transistor unit, the OLED including a light emitting area.

6. The display device as claimed in claim 5, wherein the shielding unit has an opening corresponding to the light emitting area.

7. The display device as claimed in claim 1, wherein a refractive index (n) of the first buffer layer is in a range from 1 to 2.3 for light with a wavelength of 200 nm to 510 nm.

8. The display device as claimed in claim 1, wherein an extinction coefficient (k) of the first buffer layer is in a range from 0 to 2.7 for light with a wavelength of 200 nm to 510 nm.

9. The display device as claimed in claim 1, wherein the shielding unit further comprises a second buffer layer, and the shielding layer is disposed between the first buffer layer and the second buffer layer.

10. The display device as claimed in claim 1, wherein the shielding layer is made from amorphous Si, polysilicon, crystalline Si, or a combination thereof.

11. The display device as claimed in claim 1, wherein the first buffer layer is made from silicon oxide, silicon nitride, titanium nitride, titanium silicide, aluminum oxide, nickel silicide, or a combination thereof.

12. The display device as claimed in claim 1, wherein the thin film transistor unit is a top gate thin film transistor uni or a bottom gate thin film transistor unit.

13. The display device as claimed in claim 1, wherein the semiconductor layer is an indium gallium zinc oxide (IGZO), an indium tin zinc oxide (ITZO), or other metal oxide semiconductor.

14. The display device as claimed in claim 1, wherein the semiconductor layer is amorphous Si, polysilicon, or crystalline Si.

15. The display device as claimed in claim 1, wherein the semiconductor layer is an organic semiconductor of P13, DH4T, or pentacene.

16. The display device as claimed in claim 1, wherein the display device is an organic light emitting diode display device or a liquid crystal display device.
